(19) United States
(12) Patent Application Publication
(10) Pub. No.: US 2012/0275088 A1
(43) Pub. Date: Nov. 1, 2012

(54) MULTI-LAYER ADHESIVE ASSEMBLIES FOR ELECTRONIC DEVICES

(76) Inventor: Wayne W. Huang, Cupertino, CA (US)

(21) Appl. No.: 13/095,762

(22) Filed: Apr. 27, 2011

(51) Int. Cl. H05K 7/00; B32B 17/06; B05D 5/10; B32B 7/02; B31B 1/62

(52) U.S. Cl. 361/679.01; 428/354; 428/345; 428/214; 428/201; 156/60; 427/516; 427/207.1; 428/426

(57) ABSTRACT

Techniques or processes for producing assemblies using adhesives and substrate material, such as glass. In one embodiment, the assemblies may be for portable electronic devices. For example, a cover glass of a portable electronic device may have a first layer of a self-leveling adhesive, which may be adhesively coupled with the cover glass. A second layer of a second adhesive, which may be different than the self-leveling adhesive of the first layer, may be adhesively coupled with the first layer. An optical component may be adhesively coupled with the second layer, so as to secure the optical component. The first layer may be cured prior to securing the optical component, so that the optical component may be substantially isolated from stress effects of adhesive cure shrinkage of the first layer. Flexure, warpage or optical distortion of the optical component due to adhesive cure shrinkage may be substantially avoided.

### BACKGROUND OF THE INVENTION

1. Field of the Invention

This relates generally to assemblies using substrate materials, such as glass, and adhesives.

2. Description of the Related Art

Various assemblies and assembly methods are known. For example, precision machined optical housings and optical mounts have been used in optical assemblies and the like. Such arrangements may provide advantages in rugged assemblies with precise optical alignment. However, despite such advantages, further improvements may be needed. For example, such arrangements may be heavy or bulky. They also may be expensive, time consuming, or difficult to manufacture.

Manufacturing challenges may be particularly difficult in the case of thin or low profile portable electronic devices that integrate one or more optical components. Examples of thin or low profile portable electronic devices that integrate optical components, and which have achieved great popularity with consumers, are the iPhone™ products offered by Apple Inc. of Cupertino, Calif. In such devices, adhesives can be used in forming optical assemblies. In such cases the adhesives can be optically transparent and thus suitable for the optical assemblies. Unfortunately, however, adhesives when they cure undergo shrinkage that can cause undesired curvature, warping and the like that can cause undesired optical distortion.

Thus, there is a need for improved assembly approaches for assemblies that utilize adhesives, particularly for small scale assemblies such as found in low profile portable electronic devices.

### SUMMARY

The invention pertains to techniques or processes for producing assemblies using adhesives and substrate material, such as glass. In one embodiment, the assemblies may be for portable electronic devices. For example, a cover glass of a portable electronic device may have a first layer of a self-leveling adhesive, which may be adhesively coupled with the cover glass. A second layer of a second adhesive, which may be different than the self-leveling adhesive of the first layer, may be adhesively coupled with the first layer. An optical component may be adhesively coupled with the second layer, so as to secure the optical component. The first layer may be cured prior to securing the optical component, so that the optical component may be substantially isolated from stress effects of adhesive cure shrinkage of the first layer. Flexure, warpage or optical distortion of the optical component due to adhesive cure shrinkage may be substantially avoided.

Uncured viscosity of the first layer may be substantially lower than uncured viscosity of the second layer. While the first layer is uncured, the first layer may have a sufficiently low uncured viscosity, so as to provide for self leveling of the self-leveling adhesive. The first layer may be allowed to self level, prior to curing. The first layer may also be patterned. While the second layer is uncured, the second layer may have a high uncured viscosity. The second layer may be formed thinly. The second layer may also be patterned. Thickness of the second layer may be substantially thinner than thickness of the first layer. Adhesive cure shrinkage of the second layer may be substantially less than adhesive cure shrinkage of the first layer.

The invention can be implemented in numerous ways, including as a method, system, device, or apparatus. Several embodiments of the invention are discussed below.

As an apparatus, one embodiment can, for example, include at least a substrate, a first layer of a self-leveling adhesive provided on a surface of the substrate, with the first layer having a first layer thickness, and a second layer of a second adhesive provided on and adhesively coupled to the first layer. The second adhesive can be different than the self-leveling adhesive of the first layer, and the second layer can have a second layer thickness.

As a portable electronic device, one embodiment can, for example, include at least a cover glass, a first adhesive layer of low viscosity adhesive having a first layer thickness and adhesively coupled to the cover glass, a second adhesive layer of high viscosity adhesive having a second layer thickness and adhesively coupled to the first adhesive layer; and an optical component adhesively coupled to the second adhesive layer.

As an assembly method, one embodiment can, for example, include at least forming a first layer of a self-leveling adhesive, wherein an uncured viscosity of the self-leveling adhesive is sufficiently low so as to provided for self leveling. The assembly method can then include allowing the self-leveling adhesive to self level, and then curing the first layer of the self-leveling adhesive. Still further, the assembly method can include adhesively coupling an assembly component to the first layer after the first layer is cured.

As an assembly method, another embodiment can, for example, include at least forming a first layer of a first adhesive on a substrate, curing the first layer of the first adhesive, and substantially isolating an assembly component from stress of adhesive cure shrinkage of the first layer by adhesively coupling the assembly component to the first layer after the first layer is cured.

As an assembly method, still another embodiment can, for example, include at least patterning a first layer of low viscosity adhesive on a substantially optically transparent substrate, allowing the first layer of low viscosity adhesive to self level, subsequently curing the first layer of low viscosity adhesive, and patterning a second layer of adhesive on the first layer of low viscosity adhesive. The second layer of adhesive typically has a viscosity that is higher than the viscosity of the first layer of low viscosity adhesive.

Other aspects and advantages of the invention will become apparent from the following detailed description taken in conjunction with the accompanying drawings which illustrate, by way of example, the principles of the invention.

### BRIEF DESCRIPTION OF THE DRAWINGS

The invention will be readily understood by the following detailed description in conjunction with the accompanying drawings, wherein like reference numerals designate like structural elements, and in which:

FIGS. 1A-1B show various views of one embodiment.

FIG. 2 is a diagram of an assembly state machine according to one embodiment.

FIG. 3A is a partial cutaway view of one embodiment

FIG. 3B is an exploded view of the partial cutaway view shown in FIG. 3A.

FIGS. 4A-4E are sequential partial cutaway views illustrating assembly according to one embodiment.

FIG. 5 is a flow diagram of an assembly process according to one embodiment.

FIG. 6 is another flow diagram of another assembly process.

### DETAILED DESCRIPTION OF EMBODIMENTS OF THE INVENTION

The invention pertains to assemblies using substrate materials, such as glass, and adhesives. The assemblies can be used in devices, such as electronic devices (e.g., portable electronic devices). The assemblies can be used to secure optical components to substrate materials. In one embodiment, a multi-layer adhesive stack can be used. The multi-layer adhesive stack can include a first layer of adhesive (e.g., self-leveling adhesive) that adhesively couples with a substrate material, which can be a cover glass for a portion of a housing for an electronic device. The multi-layer adhesive stack can also include a second layer of adhesive that is provided on the first layer of adhesive, after the first layer of adhesive has been cured. An optical component may be adhesively coupled with the second layer of adhesive such that the optical component is adhered to the substrate material by way of the multi-layer adhesive stack.

The following detailed description is illustrative only, and is not intended to be in any way limiting. Other embodiments will readily suggest themselves to skilled persons having the benefit of this disclosure. Reference will now be made in detail to implementations as illustrated in the accompanying drawings. The same reference indicators will generally be used throughout the drawings and the following detailed description to refer to the same or like parts. It should be appreciated that the drawings are generally not drawn to scale, and at least some features of the drawings have been exaggerated for ease of illustration.

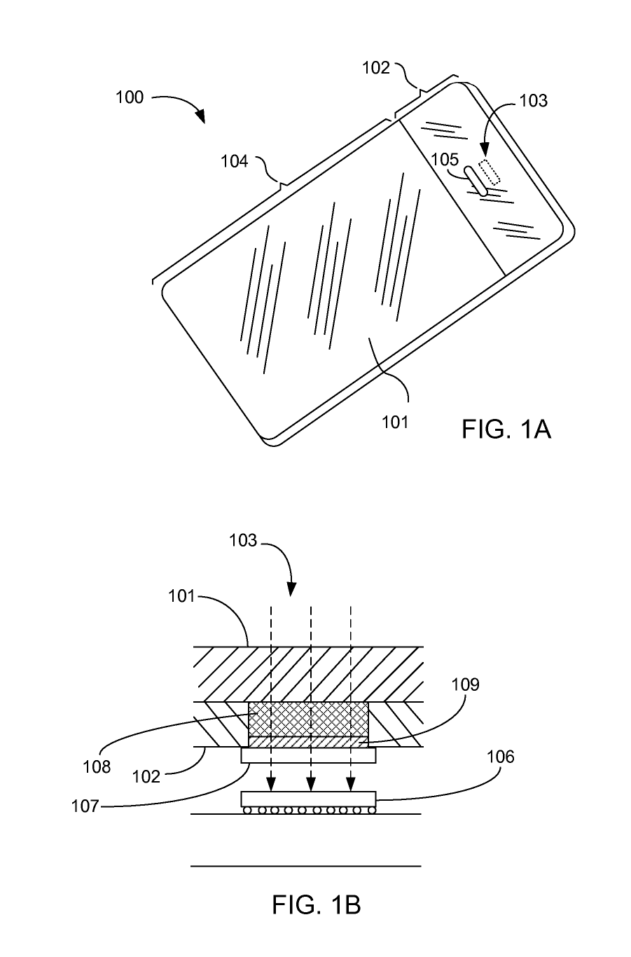

Exemplary embodiments are discussed below with reference to FIGS. 1A-6. However, those skilled in the art will readily appreciate that the detailed description given herein with respect to these figures is for explanatory purposes as the invention extends beyond these limited embodiments.

FIGS. 1A-1B show various views of one embodiment. FIG. 1A is a top perspective view of a portable electronic device 100 having a cover glass 101. Cover glass 101 (or, more generally, substrate or optical substrate) may be substantially optically transparent. A cosmetic layer 102 may coupled beneath a portion of the cover glass 101 (e.g., on a portion of an inner surface of the cover glass 101) for providing a predetermined visual appearance that is viewable through the cover glass 101 by a user. The predetermined visual appearance of the cosmetic layer 102 may, for example, be a color, such as white. In one embodiment, the cosmetic layer 102 can be provided by ink or paint applied to a portion of an inner surface of the glass cover 101.

An aperture may extend through the cosmetic layer 102 adjacent to a region 103 for a sensor 106 of the portable electronic device 100. In one embodiment, the sensor 106 can be a light sensor, such as ambient light sensor. The ambient light sensor can be used in adjusting brightness of a display disposed beneath the cover glass 101 at a display region 104 of the portable electronic device 100. Control logic of the portable electronic device 100 may adjust the display for higher or lower brightness in response to data secured by the ambient light sensor. An aperture 105 may extend through the cover glass 101, so as to provide for transmission of sound from a speaker disposed beneath the cover glass 101.

FIG. 1B shows a detailed partial cutaway view of the region 103 for the sensor 106 disposed beneath the cover glass 101. Ambient light is depicted in FIG. 1B as notional dashed arrows extending through cover glass 101 and through the aperture in the cosmetic layer 102, and through optical component 107 to reach the sensor 106, which can be an ambient light sensor. The sensor 106 may be arranged adjacent to the optical component 107, or the sensor 106 may be separated from the optical component 107 by an air gap.

The optical component 107 may comprise an optical filter. The optical component 107 may be substantially flexible, and may be substantially optically flat. For example, the optical filter 107 may comprise a flat piece of flexible polyethylene film having a coating for filtering particular frequencies of ambient light. For example, the optical filter may filter out particular frequencies of ultraviolet light, while passing other frequencies.

At least a portion of a first layer 108 of a self-leveling adhesive may be disposed in the aperture extending through cosmetic layer 102. The first layer 108 of the self-leveling adhesive may be adhesively coupled with the cover glass 101. The first layer 108 of the self-leveling adhesive may be substantially optically transparent.

A second layer 109 of a second adhesive may be different than the self-leveling adhesive of the first layer 108. At least a portion of the second layer 109 of the second adhesive may likewise be disposed at least partially in the aperture extending through cosmetic layer 102. The second layer 109 of the second adhesive may also be substantially optically transparent.

In one embodiment, the adhesives used can be optically transparent, such as Loctite™ brand adhesives, which are curable by ultraviolet light, and which may be supplied by Henkel AG & Co. KGaA. The uncured viscosity of the first layer 108 of the self-leveling adhesive may be substantially lower than uncured viscosity of the second layer 109 of the second adhesive. While the first layer is uncured, the first layer may have a sufficiently low uncured viscosity, so as to provide for self leveling of the self-leveling adhesive. For example, the uncured viscosity of the self-leveling adhesive of the first layer 108 may be approximately five thousand centipoise (5,000 cP). The first layer 108 may be allowed to self level prior to curing. The first layer 108 may be patterned in a first preselected pattern using, for example, silk screening techniques.

Similarly, the second layer 109 may be patterned in a second preselected pattern using, for example, using silk screening techniques. While the second layer is uncured, the second layer may have a high uncured viscosity. For example, the uncured viscosity of the second adhesive of the second adhesive may be approximately twenty-five thousand centipoise (25,000 cP). The second adhesive of the second layer 109 may have an uncured viscosity that is substantially higher than the uncured viscosity of the self-leveling adhesive of the first layer. For example, in one embodiment, the uncured viscosity of the second adhesive of the second layer 109 can be at least three times (3×) that of the uncured viscosity of the self-leveling adhesive of the first layer 108. As another example, in another embodiment, the uncured viscosity of the second adhesive of the second layer 109 can be about five times (5×) that of the uncured viscosity of the self-leveling adhesive of the first layer 108.

The second layer 109 of the second adhesive may be adhesively coupled with the first layer 108. The second layer 109 of the second adhesive may directly contact the first layer 108 of the self-leveling adhesive. The optical component 107 may be adhesively coupled to the second layer 109 of the second adhesive. Accordingly, the second layer 109 of the second adhesive may adhesively couple the optical component 107 to the first layer 108.

The first layer 108 may be cured prior to securing the optical component 107, so that the optical component 107 may be substantially isolated from stress effects of adhesive cure shrinkage of the first layer 108. Flexure, warpage or optical distortion of the optical component 107 may be substantially avoided. Once the optical component is placed on the second layer 109, the second layer of the second adhesive can be cured.

As will be discussed in greater detail subsequently herein, the second layer 109 may be formed thinly. Thickness of the second layer 109 may be substantially thinner than thickness of the first layer 108. Adhesive cure shrinkage of the second layer 109 may be substantially less than adhesive cure shrinkage of the first layer 108. The second layer 109 of the second adhesive may be formed sufficiently thin so as to substantially reduce the amount of stress by adhesive cure shrinkage of the second layer 109 that may be imposed on the optical component 107 that is adhered to the second layer.

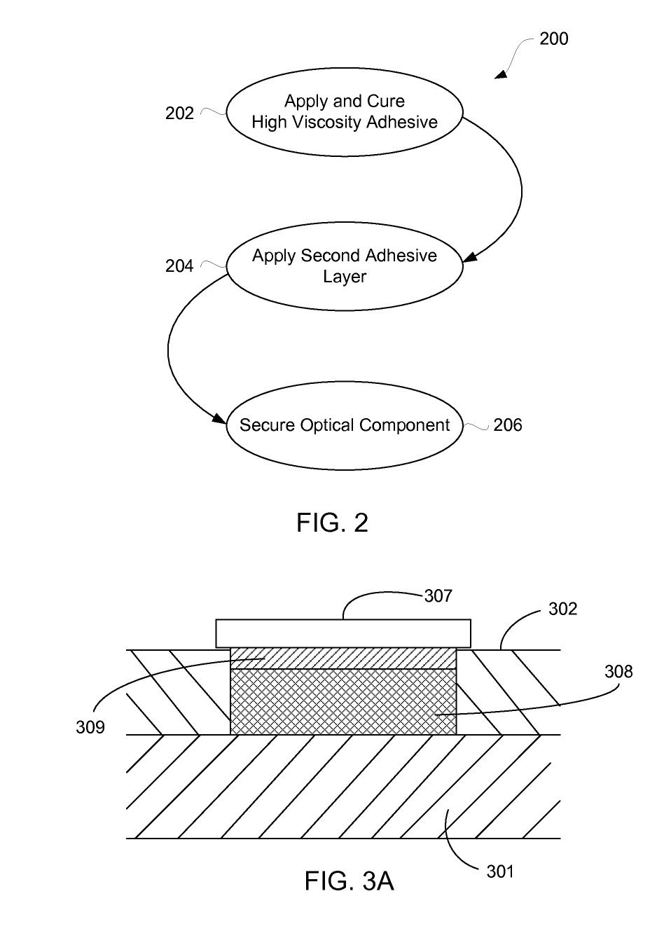

FIG. 2 is a diagram of an assembly state machine 200 according to one embodiment. The assembly state machine 200 reflects three (3) basic states associated with assembly formation. The assembly state machine 200 may include an initial state 202 of applying and curing a first layer of high viscosity adhesive. At the initial state 202, the high viscosity adhesive can be allowed to self level and then be cured. For example, in a case where the high viscosity adhesive is curable by ultraviolet light, such ultraviolet light may be used for curing the high viscosity adhesive.

Next, the assembly state machine 200 can transition to a state 204 wherein a second layer of a second adhesive may be applied. The second adhesive can be a low viscosity adhesive. Next, the assembly state machine 200 can transition to a component assembly state 206 where an optical component may be secured to the now cured first layer of the high viscosity adhesive by the second layer of the second adhesive. For example, in a case where the second adhesive is curable by ultraviolet light, such ultraviolet light may be used for curing the second adhesive and thereby securing the optical component to the second layer of the second adhesive.

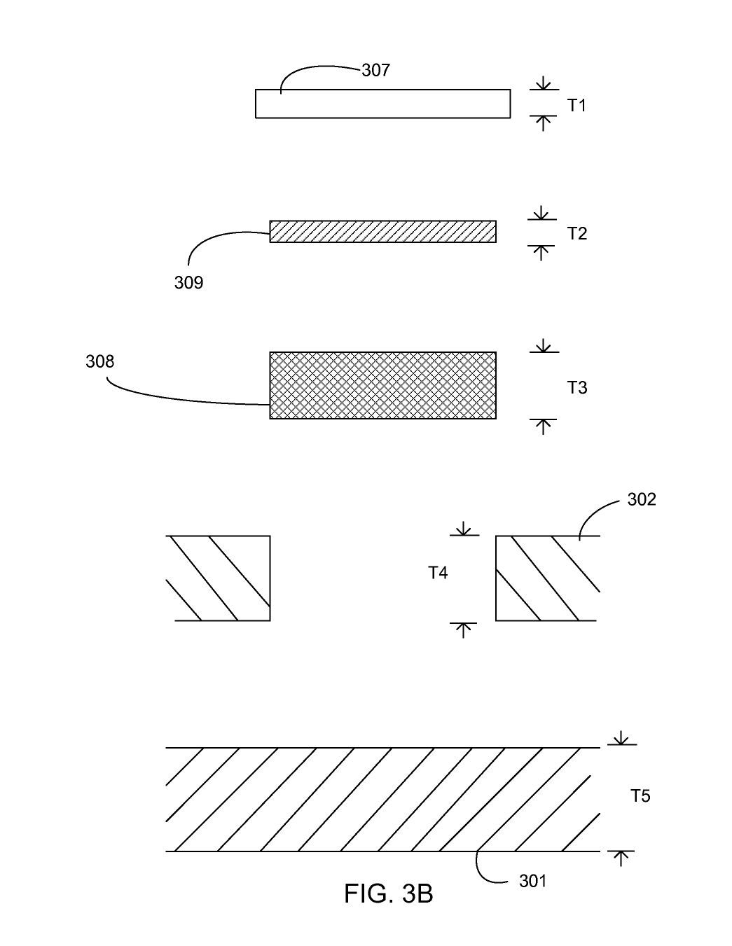

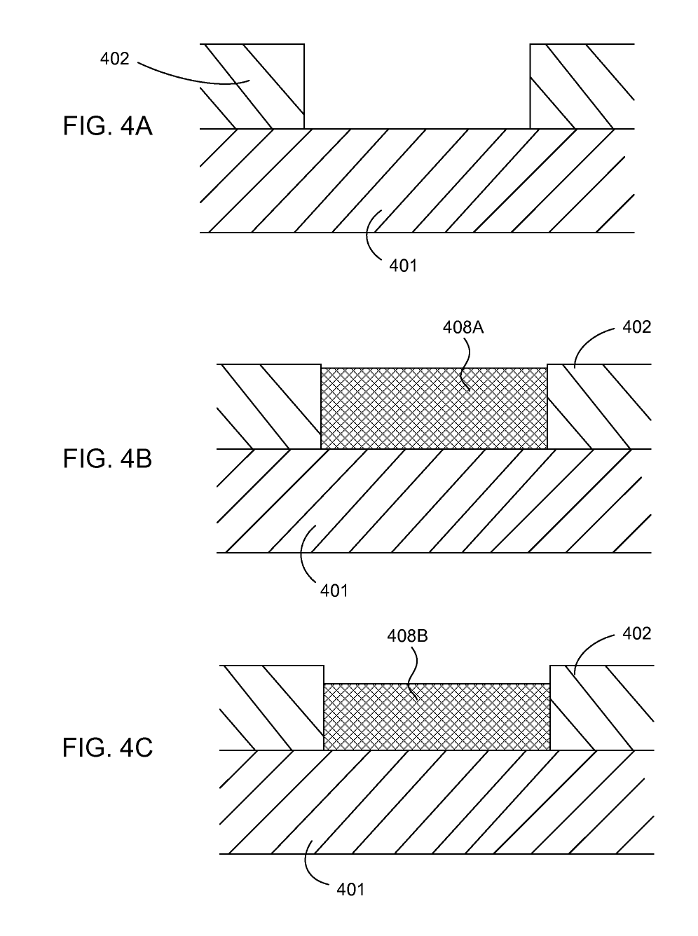

FIG. 3A is a partial cutaway view of one embodiment showing a substrate 301 (for example, glass substrate or more particularly cover glass), a cosmetic layer 302, a first layer 308 of self-leveling adhesive, a second layer 309 of second adhesive, and an optical component 307.

FIG. 3B is an exploded view of the partial cutaway view shown in FIG. 3A. As shown in FIG. 3B, the optical component 307 may have a thickness “T1” of approximately 0.07 millimeters. As mentioned previously herein, the second layer 309 may be formed thinly. Thickness “T2” of the second layer 309 may be substantially thinner than thickness “T3” of the first layer 308. Adhesive cure shrinkage of the second layer 309 may be substantially less than adhesive cure shrinkage of the first layer 308. The second layer 309 of the second adhesive may be formed sufficiently thin so as to substantially reduce stress imposed on the optical component 307 by adhesive cure shrinkage of the second layer 309. The second layer 309 of second adhesive may have a second layer thickness “T2” of approximately 0.01 millimeters. The first layer 308 of self-leveling adhesive may have thickness “T3” of approximately 0.045 millimeters. The cosmetic layer 302 may be thick, and more particularly may have a thickness “T4” of up to approximately 0.05 millimeters. The substrate 301, which may be glass such as cover glass, may have a thickness “T5” of approximately 0.5-2.5 millimeters. It should be understood that the dimensions T1-T5 discussed above regarding FIG. 3B are exemplary and can vary considerable in other embodiments.

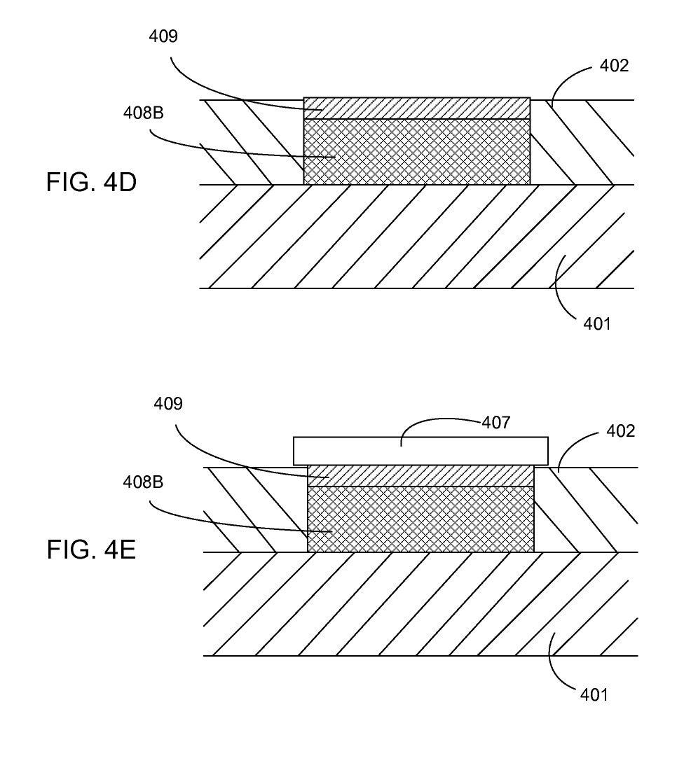

FIG. 4A-4E are sequential partial cutaway views illustrating assembly according to one embodiment. FIG. 4A shows an initial partial cutaway view of a substrate 401 and a cosmetic layer 402 having an aperture 403 extending there through. The size of the aperture 403 is typically rather small since the assembly is often for a compact electrical device. In one embodiment, the aperture 403 has a dimension (length and/or width) that is less than one centimeter. For example, the length and width of the aperture 403 can be 0.5×0.25 centimeters. Next, FIG. 4B shows a first layer 408A of uncured self-leveling adhesive disposed in the aperture. As shown in FIG. 4B, the first layer 408A of uncured self-leveling adhesive may be allowed to self level prior to curing. Next, after curing using for example ultraviolet light, FIG. 4C shows a first layer 408B of cured self-leveling adhesive. Side by side comparison of FIGS. 4B and 4C highlights adhesive cure shrinkage of the first layer 408B of the cured self-leveling adhesive, relative to the first layer 408A of the uncured self-leveling adhesive. However, the curing can cause the upper surface to deform from a flat surface (not shown) which could lead to optical distortion and other irregularities if an optical component were to be directly attached.

Next, FIG. 4D shows a second layer 409 of second adhesive which has been deposited on the upper surface of the first layer 408B. Next FIG. 4E shows securing of an optical component 407 against the second layer 409. The optical component 407 may be pressed into place by a fixture (e.g., planar metal surface, such as Teflon™ coated steel) as the second layer 409 of second adhesive is cured, for example by ultraviolet light. As illustrated by comparison of the figures, adhesive cure shrinkage of the second layer 409 is substantially less than adhesive cure shrinkage of the first layer 408A, 408B (and thus remains substantially flat and optically uniform). Hence, adhesive cure shrinkage imposed on the optical component 407 is only than amount due to the second layer 409 of second adhesive because the first layer 408B is isolated from the upper surface of the second layer 409 that receives the optical component 407.

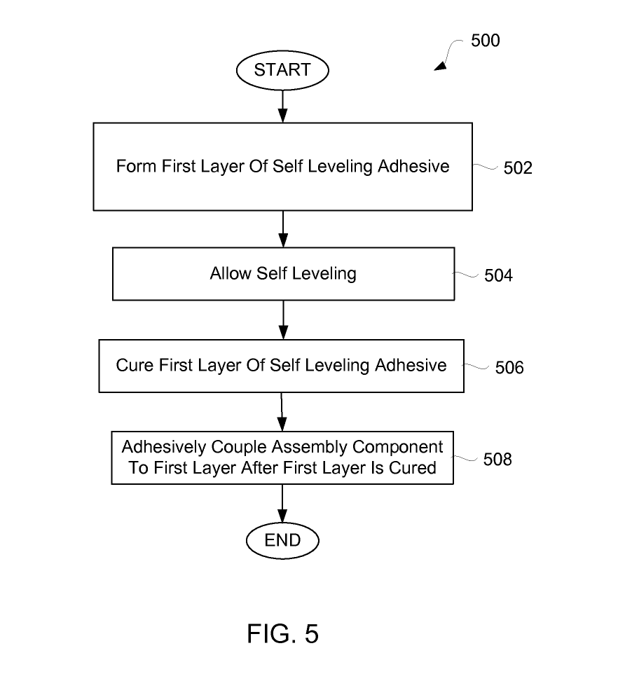

FIG. 5 is a flow diagram of an assembly process 500 according to one embodiment. The assembly process 500 may begin with forming 502 a first layer of a self-leveling adhesive on a substrate. The first layer of the self-leveling adhesive can be formed 502, for example, using silk screening techniques. The forming the first layer may comprise patterning the first layer in a first preselected pattern.

After the forming 502 the first layer, the self-leveling adhesive may be allowed 504 to self level. The first layer may then be cured 506. For example, in a case where the self-leveling adhesive is curable by ultraviolet light, such ultraviolet light may be used for curing the self-leveling adhesive.

After the self-leveling adhesive of the first layer has been cured 506, an assembly component may be adhesively coupled 508 to the first layer. In particular, the adhesively coupling 508 of the assembly component may comprise adhesively coupling an optical component to the first layer. Following the block 508 of adhesively coupling the assembly component, the assembly process 500 shown in FIG. 5 can end.

The adhesive coupling 508 may comprise forming a second layer of a second adhesive that is different than the self-leveling adhesive of the first layer. In particular, the second adhesive may have an uncured viscosity that is substantially higher than the uncured viscosity of the self-leveling adhesive of the first layer. For example the uncured viscosity of the second adhesive of the second adhesive may be approximately twenty-five thousand centipoise (25,000 cP), which is considered low viscosity. The uncured viscosity of the self-leveling adhesive may be approximately five thousand centipoise (5,000 cP), which is considered high viscosity. The adhesively coupling 508 may comprise patterning the second layer of the second adhesive in a second preselected pattern, for example, by using silk screening techniques.

The adhesive coupling 508 may comprises forming the second layer of the second adhesive so as to have a thickness that is thinner than a thickness of the first layer. The second layer of the second adhesive may be cured, for example using ultraviolet light, and may having an adhesive cure shrinkage that is less than an adhesive cure shrinkage of the first layer. The second layer of second adhesive can be sufficiently thin so as to substantially reduce stress on the assembly component due to adhesive cure shrinkage of the second layer.

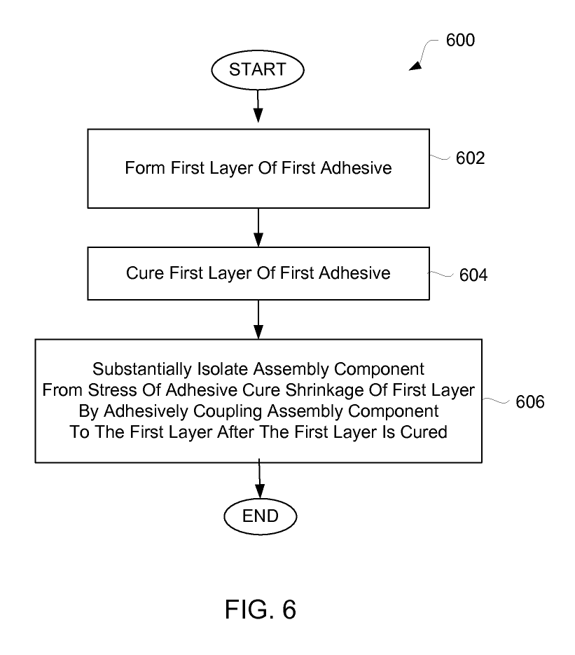

FIG. 6 is another flow diagram of another assembly process 600. The assembly process 600 may begin with forming 602 a first layer of a first adhesive. The assembly process may continue with curing 604 the first layer of the first adhesive. For example, in a case where the first adhesive is curable by ultraviolet light, such ultraviolet light may be used for curing the first adhesive.

The assembly process may continue with substantially isolating 606 an assembly component from stress of adhesive cure shrinkage of the first layer, by adhesively coupling the assembly component to the first layer after the first layer is cured. For example, a second layer of a second adhesive may be used for adhesively coupling the assembly component to the first layer after the first layer is cured. After block 606 of substantially isolating the assembly component from stress of adhesive cure shrinkage of the first layer, the assembly process 600 can end.

The assembly processes are, in one embodiment, particularly well-suited for a portable electronic device. Examples of such portable electronic devices may be mobile telephones (e.g., cell phones), Personal Digital Assistants (PDAs), portable media players, remote controllers, pointing devices (e.g., computer mouse), game controllers, tablet computers, laptop computers, etc.

The portable electronic device can further be a hand-held electronic device. The term hand-held generally means that the electronic device has a form factor that is small enough to be comfortably held in one hand. A hand-held electronic device may be directed at one-handed operation or two-handed operation. In one-handed operation, a single hand is used to both support the device as well as to perform operations with the user interface during use. In two-handed operation, one hand is used to support the device while the other hand performs operations with a user interface during use or alternatively both hands support the device as well as perform operations during use. In some cases, the hand-held electronic device is sized for placement into a pocket of the user. By being pocket-sized, the user does not have to directly carry the device and therefore the device can be taken almost anywhere the user travels (e.g., the user is not limited by carrying a large, bulky and often heavy device).

The various aspects, features, embodiments or implementations of the invention described above can be used alone or in various combinations.

Different aspects, embodiments or implementations may, but need not, yield one or more of the following advantages. One advantage is manufacturability and/or ease of assembly from using adhesives. Another advantage is efficiency from self leveling of self-leveling adhesives. Another advantage is that flexure, warpage or optical distortion with assembly of optical component using adhesives may be substantially avoided. Another advantage is that an optical component being assembled with adhesives may remain substantially optically flat. Another advantage is that a multi-layer adhesive build-up can be used to substantially reduce stress on an assembly component caused by adhesive cure shrinkage of the adhesive. Another advantage is that an assembly component (or in particular an optical component) may be assembled with adhesive while being substantially isolated from stress effects of adhesive cure shrinkage.

The many features and advantages of the present invention are apparent from the written description. Further, since numerous modifications and changes will readily occur to those skilled in the art, the invention should not be limited to the exact construction and operation as illustrated and described. Hence, all suitable modifications and equivalents may be resorted to as falling within the scope of the invention.

What is claimed is:

1. An apparatus, comprising:
a substrate;
a first layer of a self-leveling adhesive provided on a surface of the substrate, the first layer having a first layer thickness; and
a second layer of a second adhesive provided on and adhesively coupled to the first layer, the second adhesive being different than the self-leveling adhesive of the first layer, the second layer having a second layer thickness.

2. An apparatus as recited in claim 1, wherein the first layer of the self-leveling adhesive and the second layer of the second adhesive are curable by ultraviolet light.

3. An apparatus as recited in claim 1, wherein the second layer thickness is substantially thinner than the first layer thickness.

4. An apparatus as recited in claim 1, wherein adhesive cure shrinkage of the second layer is substantially less than adhesive cure shrinkage of the first layer.

5. An apparatus as recited in claim 1, wherein the apparatus further comprises:
an optical component adhesively coupled to the first layer via the second layer.

6. An apparatus as recited in claim 5, wherein the optical component is a film.

7. An apparatus as recited in claim 5, wherein the optical component is a configured to be substantially flat while adhesively coupled to the second layer.

8. An apparatus as recited in claim 1, wherein the apparatus further comprises:
an optical filter adhesively coupled to the first layer by the second layer.

9. An apparatus as recited in claim 1, further comprising an optical component that is substantially optically flat.

10. An apparatus as recited in claim 1, wherein the first layer is substantially optically transparent, and wherein the second layer is substantially optically transparent.

11. An apparatus as recited in claim 1, wherein at least a portion of the substrate adjacent the first layer is substantially optically transparent.

12. An apparatus as recited in claim 1, wherein the first layer directly contacts the second layer.

13. An apparatus as recited in claim 1, wherein the first layer of self-leveling adhesive is patterned in a preselected first pattern, and wherein the second layer of the second adhesive is patterned in a preselected second pattern.

14. A portable electronic device, comprising:
a cover glass;
a first adhesive layer of low viscosity adhesive having a first layer thickness and adhesively coupled to the cover glass;
a second adhesive layer of high viscosity adhesive having a second layer thickness and adhesively coupled to the first adhesive layer; and
an optical component adhesively coupled to the second adhesive layer.

15. A portable electronic device as recited in claim 14, wherein the optical component comprises an optical filter.

16. A portable electronic device as recited in claim 15, wherein the optical filter substantially blocks UV light.

17. A portable electronic device as recited in claim 16, wherein the portable electronic device further comprises a light sensor arranged adjacent to the optical filter.

18. A portable electronic device as recited in claim 14, wherein the second layer thickness is substantially thinner than the first layer thickness.

19. A portable electronic device as recited in claim 14, wherein adhesive cure shrinkage of the second adhesive layer is substantially less than adhesive cure shrinkage of the first adhesive layer.

20. A portable electronic device as recited in claim 14, wherein the portable electronic device further comprises:
at least one cosmetic layer coupled to the cover glass for providing a predetermined visual appearance that is viewable through the cover glass by a user; and
an aperture extending through the cosmetic layer,
wherein at least a portion of the first adhesive layer is disposed within the aperture.

21. A portable electronic device as recited in claim 19, wherein at least a portion of the second adhesive layer is disposed within the aperture.

22. A portable electronic device as recited in claim 19, wherein the predetermined visual appearance is substantially white.

23. A portable electronic device as recited in claim 14, wherein the high viscosity adhesive has a viscosity that is at least three times that of the low viscosity adhesive.

24. A portable electronic device as recited in claim 19, wherein the aperture as a dimension that is less than one centimeter.

25. An assembly method, comprising:
forming a first layer of a self-leveling adhesive, wherein an uncured viscosity of the self-leveling adhesive is sufficiently low so as to provided for self leveling;
allowing the self-leveling adhesive to self level;
curing the first layer of the self-leveling adhesive; and
adhesively coupling an assembly component to the first layer after the first layer is cured.

26. An assembly method as recited in claim 25, wherein the curing comprises ultraviolet light curing.

27. An assembly method as recited in claim 25, wherein the adhesively coupling the assembly component comprises adhesively coupling an optical component to the first layer.

28. An assembly method as recited in claim 25,
wherein the forming the first layer comprises patterning the first layer in a first preselected pattern, and
wherein the adhesively coupling comprises patterning a second layer of a second adhesive in a second preselected pattern.

29. An assembly method as recited in claim 25, wherein the adhesively coupling comprises forming a second layer of a second adhesive that is different than the self-leveling adhesive of the first layer.

30. An assembly method as recited in claim 25, wherein the adhesively coupling comprises forming a second layer of a second adhesive having an uncured viscosity that is substantially higher than the uncured viscosity of the self-leveling adhesive of the first layer.

31. An assembly method as recited in claim 25, wherein the adhesively coupling comprises forming a second layer of a second adhesive having a thickness that is thinner than a thickness of the first layer.

32. An assembly method as recited in claim 25, wherein the adhesively coupling comprises curing a second layer of a second adhesive having an adhesive cure shrinkage less than an adhesive cure shrinkage of the first layer.

33. An assembly method, comprising:
forming a first layer of a first adhesive on a substrate;
curing the first layer of the first adhesive; and
substantially isolating an assembly component from stress of adhesive cure shrinkage of the first layer by adhesively coupling the assembly component to the first layer after the first layer is cured.

34. An assembly method, comprising:
patterning a first layer of low viscosity adhesive on a substantially optically transparent substrate;
allowing the first layer of low viscosity adhesive to self level;
subsequently curing the first layer of low viscosity adhesive; and
patterning a second layer of adhesive on the first layer of low viscosity adhesive, the second layer of adhesive having a viscosity that is higher than the viscosity of the first layer of low viscosity adhesive.
